(19) United States
(12) Patent Application Publication
(10) Pub. No.: US 2006/0240656 A1
(43) Pub. Date: Oct. 26, 2006

(54) Method for forming contact of semiconductor device by using solid phase epitaxy process

(75) Inventor: Tae-Hang Ahn, Kyoungki-dolchon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 11/323,118

(22) Filed: Dec. 29, 2005

(30) Foreign Application Priority Data
Apr. 21, 2005 (KR) 10-2005-0033316

(51) Int. Cl. H01L 21/44

(52) U.S. Cl. 438/597

(57) ABSTRACT

A method for forming a contact plug of a semiconductor device includes providing a plurality of junctions on a substrate; forming an inter-layer insulation layer over the substrate and the junctions; forming a plurality of contact holes to expose the junctions by etching the inter-layer insulation layer; forming contact layers that fill the contact holes, the contact layers including an epitaxy layer and an amorphous layer, the contact layers formed by using a solid phase epitaxy (SPE) process; and forming a plurality of cell landing plug contacts by selectively planarizing the amorphous layer of the contact layers.

### FIELD OF THE INVENTION

The present invention relates to a method for fabricating a semiconductor device; and more particularly, to a method for forming a contact plug of a semiconductor device.

### DESCRIPTION OF RELATED ARTS

As large scale integration and the small size of a semiconductor device have led to a gradual reduction of contact area, there has been an increase in contact resistance and a decrease in operation current. Accordingly, device degradation phenomena (such as a tWR fail) and a degradation in the data retention time property of the semiconductor device have been generated.

Thus, there have been suggested various methods to reduce the contact resistance and improve the operation current of the semiconductor device. One suggested method is to increase the dopant concentration of a junction region of a silicon substrate. Another suggested method is to increase the concentration of phosphorous (P) that is a dopant within polysilicon used as a contact material.

However, the polysilicon used as the contact material not only has a very high resistance itself but also contains a very thin oxide layer formed during loading a wafer to an apparatus. Thus, the polysilicon brings a limitation on decreasing the contact resistance.

Accordingly, it is difficult to decrease the contact resistance and improve a device property by using the polysilicon as the contact material as the semiconductor device has been continuously integrated.

Recently, a technology introduced to not only reduce the contact resistance but also improve the device property is an epitaxial silicon layer formed in a single type chemical vapor deposition (CVD) apparatus. A selective epitaxial growth (SEG) process and a solid phase epitaxy (SPE) process are being actively researched and developed as a process for forming the epitaxial silicon layer.

Between the aforementioned two processes, it is the SPE process capable of growing epitaxial silicon at a low temperature by being applied as it is to a process for forming a semiconductor device and sufficiently overcoming the problem with polysilicon by using a low doping concentration.

In case of using the SPE process, P is doped in an as-deposited amorphous silicon layer having a relatively low concentration ranging from approximately 5×10¹⁹ atoms/cm³ to approximately 2×10²⁰ atoms/cm³ by using a silane (SiH₄) or phosphine (PH₃) gas at a temperature ranging from approximately 500° C. to approximately 650° C. The amorphous silicon layer deposited under the above described conditions is subjected to a thermal process in a nitrogen (N₂) atmosphere at a low temperature ranging from approximately 500° C. to approximately 650° C. for a predetermined time. For instance, the thermal process can be performed at approximately 500° C. for approximately 10 hours, or the thermal process can be performed at approximately 650° C. for approximately 30 minutes. Herein, the thermal process is performed for a longer period at a lower temperature. Then, the amorphous silicon layer is re-grown as an epitaxial silicon layer.

FIG. 1A illustrates a contact material formed using a conventional solid phase epitaxy (SPE) process performed at a temperature of approximately 610° C. FIG. 1B illustrates an amorphous silicon layer within a whole contact that is re-grown into an epitaxial silicon layer after a contact material formed using a conventional SPE process is subjected to a subsequent thermal process.

Referring to FIG. 1A, in case of forming the contact material by using the SPE process, the epitaxial silicon layer A is grown on a surface of a substrate and the amorphous silicon layer B is formed on remaining areas provided with contact holes.

If the subsequent thermal process is performed in a state that both the epitaxial silicon layer and the amorphous silicon layer exist, all of the epitaxial silicon layer and the amorphous silicon layer are re-grown in the epitaxial silicon layer A′ and A″ as shown in FIG. 1B.

As described above, the contact material is formed in the epitaxial silicon layer through the SPE process and the subsequent thermal process. Then, a chemical mechanical polishing (CMP) process is performed, thereby forming a cell landing plug contact. Afterwards, a bit line contact (BLC) or a storage node contact (SNC) is formed on an upper portion of the cell landing plug contact.

However, a process for fabricating the above described conventional cell landing plug contact employed through sequentially performing the subsequent thermal process and the CMP process that re-grows the contact material in the epitaxial silicon layer provides such problems as follows.

First, the material polished during the CMP process for forming the cell landing plug contact is the epitaxial silicon layer. The epitaxial silicon layer is well known for excessively generating dishing during performing the CMP process.

For instance, during performing the CMP process, the degree of dishing generated in the case of polishing the epitaxial silicon layer or polysilicon is considerably increased compared to that generated in case of polishing the amorphous silicon layer, thereby degrading reliability and yields of the devices.

FIG. 2A illustrates dishing generated during a conventional chemical mechanical polishing (CMP) process performed on an amorphous silicon layer. FIG. 2B illustrates dishing generated during a conventional CMP process performed on an epitaxial silicon layer.

Referring to FIGS. 2A to 2B, when the CMP process is performed on the amorphous silicon layer, the dishing has height of approximately 430 Å; however, when the CMP process is performed on the epitaxial silicon layer, the dishing has height of approximately 547 Å, which is significantly greater than the former.

If a contact hole etch for forming a subsequent bit line contact is performed under a state that the dishing is excessively generated, the critical dimension (CD) of the contact hole is considerably decreased. Thus, there is a high possibility that a semiconductor device completed with the above contact hole would fail, thereby decreasing product yields. FIG. 2C illustrates the decrease of the CD of a bit line contact (BLC) when a contact hole etch for forming a subsequent bit line contact is performed on a conventional material with excessive dishing.

### SUMMARY OF THE INVENTION

The present embodiment relates to providing a method for fabricating a contact plug in a semiconductor device that does not result in excessive dishing phenomenon.

In accordance with one aspect of the present invention, a method for forming a contact of a semiconductor device, includes: providing a plurality of junctions on a substrate; forming an inter-layer insulation layer on a substrate formed thereon a plurality of junctions; forming a plurality of contact holes to expose the junctions by etching the inter-layer insulation layer; performing a pre-cleaning process for removing a native oxide layer on a bottom surface of the contact holes; forming contact layers filling the contact holes and comprised of an epitaxy layer and an amorphous layer by using a solid phase epitaxy (SPE) process; and forming a plurality of cell landing plug contacts by selectively planarizing an amorphous layer of the contact layers.

### BRIEF DESCRIPTION OF THE DRAWINGS

FIG. 1A illustrates a contact material formed using a conventional solid phase epitaxy (SPE) method performed at a temperature of approximately 610° C.

FIG. 1B illustrates an amorphous silicon layer within a whole contact that is re-grown into an epitaxial silicon layer after a contact material formed using a conventional SPE method is subjected to a subsequent thermal process.

FIG. 2A illustrates dishing generated during a conventional chemical mechanical polishing (CMP) process performed on an amorphous silicon layer.

FIG. 2B illustrates dishing generated during a conventional CMP process performed on an epitaxial silicon layer;

FIG. 2C illustrates the decrease of a critical dimension (CD) of a bit line contact (BLC) when a contact hole etch for forming a subsequent bit line contact is performed on a conventional contact material with excessive dishing.

FIGS. 3A to 3D are cross-sectional views illustrating a method for forming a contact plug in a semiconductor device in accordance with one embodiment of the present invention.

FIG. 4 illustrates a result obtained after employing a CMP process according to one embodiment of the present invention.

FIGS. 5A to 5C are cross-sectional views illustrating a method for forming a contact plug in a semiconductor device in accordance with another embodiment of the present invention.

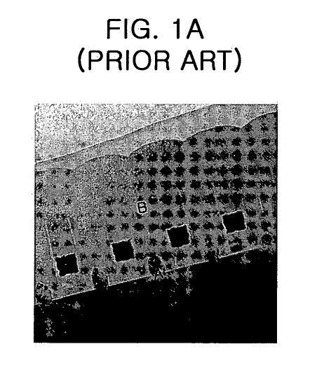

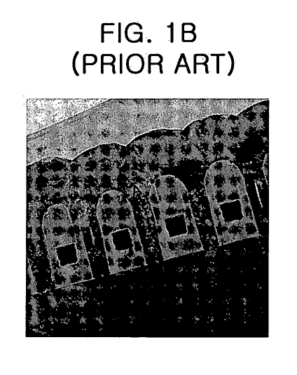

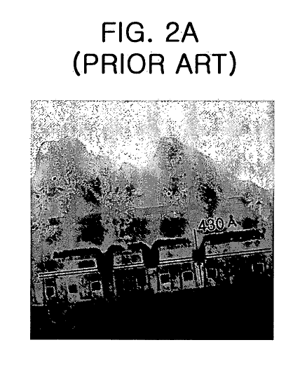

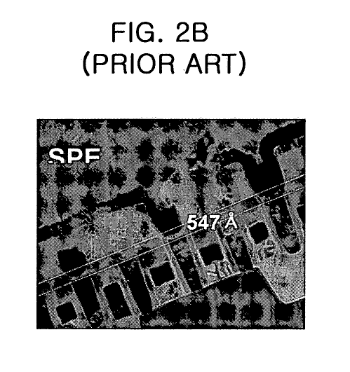

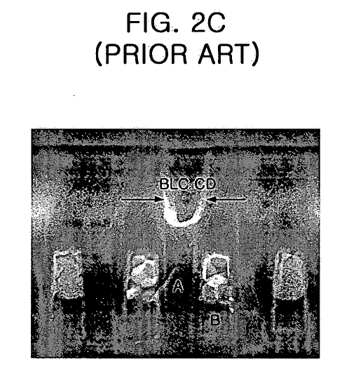

### DETAILED DESCRIPTION OF THE INVENTION

Hereinafter, detailed descriptions on a preferred embodiment of the present invention will be provided with reference to the accompanying drawings.

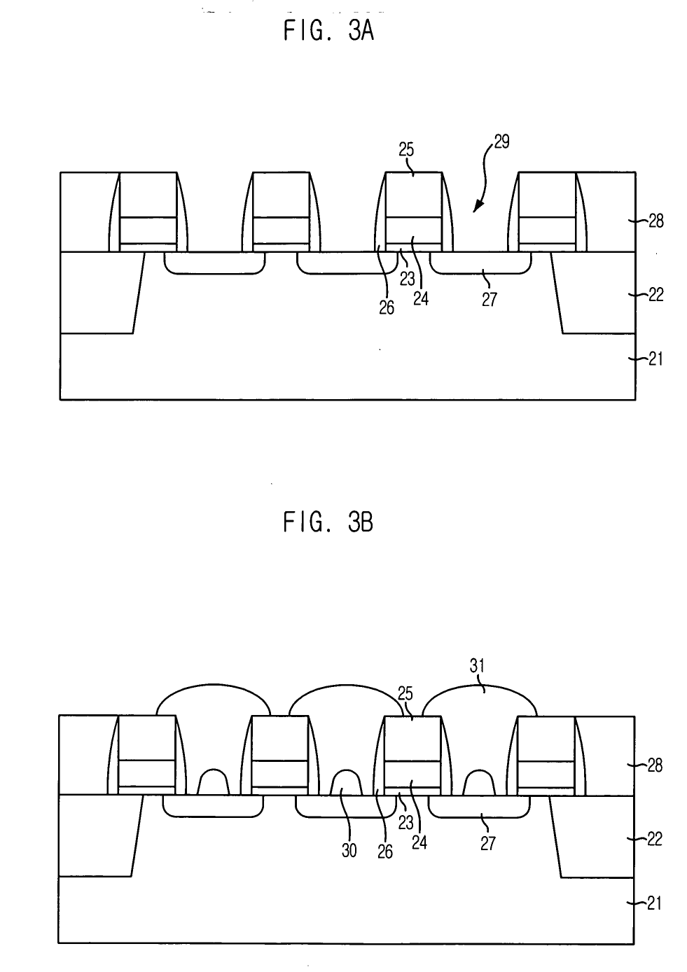

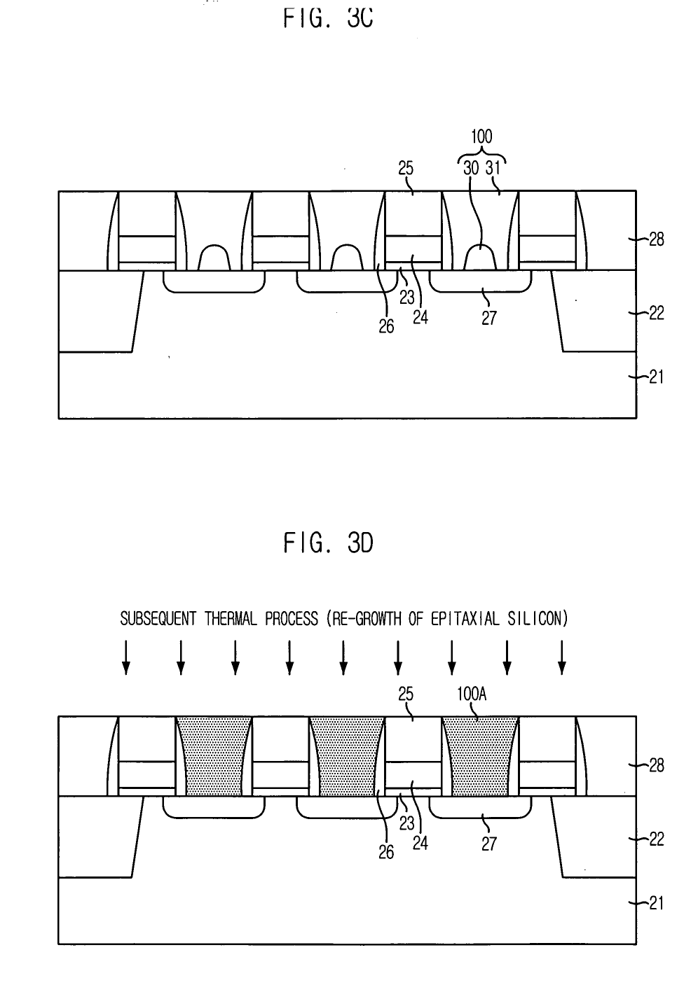

FIGS. 3A to 3D are cross-sectional views illustrating a method for forming a contact of a semiconductor device in accordance with one embodiment of the present invention.

As shown in FIG. 3A, a device isolation process for isolating devices from each other is performed on a substrate 21, thereby forming a device isolation layer 22. Afterwards, a plurality of gate patterns formed by sequentially stacking a gate insulation layer 23, a gate electrode 24 and a gate hard mask 25 are formed on selected regions of the substrate 21.

Subsequently, an insulation layer is deposited on the substrate 21 including the plurality of gate patterns and then a blanket etch is performed, thereby forming a plurality of gate spacers 26 contacted on the sidewalls of the gate patterns. At this time, the gate hard mask 25 and the gate spacers 26 use a material having an etch selectivity with respect to a subsequent inter-layer insulation layer. If the inter-layer insulation layer is a silicon oxide layer, a silicon nitride layer is used for forming the gate hard mask 25 and the gate spacers 26.

Next, a plurality of junctions 27 serving the role of a source/drain of a transistor are formed on the substrate 21 exposed between the plurality of gate patterns by employing a typical ion-implantation process. Herein, the junctions 27 can be a lightly doped drain (LDD) structure, and N-type dopants such as arsenic (As) or P-type dopants such as boron (B) are implanted to the junctions 27.

Next, an inter-layer insulation layer 28 is deposited on the substrate 21 including the plurality of gate patterns. At this time, the inter-layer insulation layer 28 uses an oxide compound. Particularly, a silicon oxide-based material selected from a group consisting of borophosphosilicate glass (BPSG), undoped silicate glass (USG), tetraethylorthosilicate (TEOS), phosphosilicate glass (PSG) and borosilicate glass (BSG) is used.

Next, a chemical mechanical polishing (CMP) process is performed until upper portions of the gate patterns are exposed, thereby planarizing the inter-layer insulation layer 28. Subsequently, a contact mask is formed through a photolithography process, e.g., a deposition of a photoresist layer, and photo-exposure and developing processes. Afterwards, the inter-layer insulation layer 28 is etched by using the contact mask (not shown) as an etch mask, thereby forming a plurality of contact holes 29 for forming a cell landing plug contact.

At this time, since there is lack of a photolithography process margin with respect to a lower layer as for a highly integrated device, the inter-layer insulation layer 28 is subjected to a self-aligned contact (SAC) etching process under a condition that the etch selectivity of the inter-layer insulation layer 28 is good with respect to those of the gate hard mask 25 and the spacers 26. Accordingly, the silicon oxide-based material used for forming the inter-layer insulation layer 28 exposed through the photolithography process is etched at a fast speed. However, since the etch speed of the silicon nitride layer used for forming the gate hard mask 25 and the gate spacers 26 is slow, a silicon nitride-based layer deposited on upper portions or sidewalls of the gate patterns is more or less protected and the junctions 27 of the substrate 21 are exposed.

Meanwhile, etch residues (not shown) exist on sidewalls and low portions of the plurality of contact holes 29 formed by etching the inter-layer insulation layer 28 and a latticed silicon defect is generated on the surface of the junctions 27 due to the etching process. Furthermore, a native oxide layer is formed on surfaces of the junctions 27 exposed by forming the contact holes 29. The etch residues degrade the leakage current property of a device and the native oxide layer increases the contact resistance, thereby providing a factor degrading the electrical property of the device.

Accordingly, after the plurality of contact holes 29 are formed, a pre-cleaning process (e.g., a dry cleaning process or a wet cleaning process) is performed before forming the contact material. The wet cleaning process uses a hydrogen fluoride (HF)-last cleaning that applies a solution of HF at the last, or a buffered oxide echant (BOE)-last cleaning that uses a solution of BOE at the last. The dry cleaning process applies a plasma cleaning process and/or a thermal bake process. The pre-cleaning process is employed at a temperature ranging from approximately 25° C. to approximately 500° C.

The HF-last cleaning proceeds a HF-based cleaning at the last. The HF-last cleaning uses a chemical solution selected from a group consisting of RNO[R(H₂SO₄+H₂O₂)+N(NH₄OH+H₂O₂)+O(HF-based BOE)], RNF [R (H₂SO₄+H₂O₂)+N (NH₄OH+H₂O₂)+HF], RO, NO and RF. Herein, R is referred as SPM that is a mixture of sulfuric (H₂SO₄) and peroxide (H₂O₂).

A gas used during performing the plasma cleaning process is selected from a group consisting of an hydrogen (H₂) gas, a mixed gas of H₂ and nitrogen (N₂), a chlorine fluoride (CF) based gas, a nitrogen fluoride (NF) based gas and a nitrogen hydride (NH) based gas. For instance, H₂, H₂/N₂, nitrogen trifluoride (NF₃), ammonia (NH₃) and tetrafluoromethane (CF₄) are used.

The pre-cleaning process described above is performed continuously without a time delay to maintain a clean condition of the exposed portions of the contact holes 29 and a solid phase epitaxy (SPE) process is also performed without a time delay after employing the pre-cleaning process.

As shown in FIG. 3B, the SPE process is employed, thereby growing an amorphous silicon layer 31 filling the plurality of contact holes 29 in a thickness ranging from approximately 300 Å to approximately 3,000 Å. At this time, during the SPE process, an epitaxial silicon layer 30 is formed on the bottom surfaces of the plurality of contact holes 29 at an early deposition state. As the deposition proceeds, the amorphous silicon layer 31 is formed on the epitaxial silicon layer 30.

For instance, the SPE process for growing the epitaxial silicon layer 30 and the amorphous silicon layer 31 is employed in an H₂ atmosphere along with supplying a mixed gas of silane (SiH₄) and phosphine (PH₃) at a pressure ranging from approximately 150 torr to approximately 200 torr and a temperature ranging from approximately 400° C. to approximately 700° C. for a predetermined time. For instance, the SPE process can be performed at approximately 400° C. for approximately 20 minutes, or at approximately 700° C. for approximately 3 minutes. Herein, the SPE process is performed for a longer period at a lower temperature. At this time, a flowing amount of SiH₄ ranges from approximately 500 sccm to approximately 800 sccm and a flowing amount of PH₃ ranges from approximately 20 sccm to approximately 50 sccm. As described above, the PH₃ gas that is the doping gas is flowed while the amorphous silicon layer 31 is being grown, thereby maintaining a doping concentration of P within the amorphous silicon layer 31 at a relatively low level ranging from approximately 1×10¹⁹ atoms/cm³ to approximately 1×10²¹ atoms/cm³.

Meanwhile, it is possible to use arsenic (As) as an impurity doped within the amorphous silicon layer 31. At this time, during the growing of the amorphous silicon layer 31, arsine (AsH₃) is flowed as a doping gas. It is preferable to perform the SPE process doping As in an H₂ gas atmosphere at a pressure ranging from approximately 150 torr to approximately 200 torr and a temperature ranging from approximately 400° C. to approximately 700° C. for a predetermined time along with supplying a mixed gas of SiH₄ and AsH₃. For instance, the SPE process can be performed at approximately 400° C. for approximately 20 minutes, or can be performed at approximately 700° C. for approximately 3 minutes. Herein, the SPE process is performed for a longer period at a lower temperature. At this time, the flowing amount of SiH₄ ranges from approximately 500 sccm to approximately 800 sccm and the flowing amount of AsH₃ ranges from approximately 20 sccm to approximately 50 sccm. As shown above, the AsH₃ gas that is the doping gas is flowed while the amorphous silicon layer 31 is being grown, thereby maintaining a doping concentration of As at a relatively low level ranging from approximately 1×10¹⁹ atoms/cm³ to approximately 1×10²¹ atoms/cm³.

A deposition method for growing the amorphous silicon layer 31 through the SPE process as described above includes one selected from a group consisting of a reduced pressure chemical vapor deposition (RPCVD) method, a low pressure chemical vapor deposition (LPCVD) method, a very low pressure chemical vapor deposition (VLPCVD) method, a plasma enhanced chemical vapor deposition (PECVD) method, an ultra high vacuum chemical vapor deposition (UHVCD) method, an atmosphere pressure chemical vapor deposition (APCVD) and a molecular beam epitaxy (MBE).

Although the amorphous silicon layer 31 and the epitaxial silicon layer 30 used as the contact materials are formed through the SPE process, germanium (Ge) and silicon germanium (SiGe) in addition to silicon can also be used as the contact material formed through the SPE process. That is, it is possible to use an epitaxial Ge layer/an amorphous Ge layer and an epitaxial SiGe layer/an amorphous SiGe layer as the contact materials.

Meanwhile, the first reason why the epitaxial silicon layer 30 can grow under the early deposition state during the SPE process is because the epitaxial silicon layer 30 is loaded into an amorphous layer deposition apparatus, e.g., an amorphous silicon deposition apparatus, in a vacuum without any time delays after the pre-cleaning process is performed. During performing the pre-cleaning process, if the SPM formed by mixing approximately 1 part of H₂SO₄ and approximately 20 parts of H₂0₂ at a temperature of approximately 90° C. and a solution of BOE formed by mixing approximately 300 parts of NH₄ and 1 part of HF are used, a surface of the substrate is subjected to a hydrogen treatment, i.e., a state that a silicon dangling bond of the silicon substrate is combined with a hydrogen, thereby preventing the growth of the native oxide layer for a predetermined period. As described above, since the growth of the native oxide layer is prevented, the epitaxial silicon layer 30 is grown at the early deposition state during the SPE process. The second reason why the epitaxial silicon layer 30 can grow under the early deposition state of the SPE process is because an atmosphere gas introduced to deposit the amorphous silicon layer 31 is the H₂ gas. That is, as the H₂ gas is used, the gas atmosphere becomes a deoxidizing atmosphere instead of an oxidizing atmosphere. Thus, the epitaxial silicon layer 30 can grow even in the early deposition state of the amorphous silicon layer 31 due to the deoxidizing atmosphere.

As shown in FIG. 3C, the amorphous silicon layer 31 is subjected to a CMP process and becomes planarized, thereby forming a plurality of cell landing contact plugs 100 isolated from each other. That is, the plurality of cell landing contact plugs 100 are comprised of the epitaxial silicon layer 30 and the amorphous silicon layer 31. During the CMP process, only the amorphous silicon layer 31 is planarized.

As described above, in accordance with the present invention, a subsequent thermal process for re-growing the amorphous silicon 31 that is the contact material formed through the SPE process into the epitaxial silicon layer 31 is not performed. Instead, the CMP process is directly performed, thereby forming the plurality of cell landing plug contacts 100. The plurality of cell landing plug contacts 100 become a dual layer formed with the epitaxial silicon layer 30 and the amorphous silicon layer 31.

Accordingly, a region removed through the CMP process is the amorphous silicon layer 31 among the contact materials formed through the SPE process. Dishing caused by the CMP process employed to the amorphous silicon layer 31 is smaller than that caused by the CMP process employed to the epitaxial layer 30 by a thickness ranging from approximately 50 Å to approximately 100 Å, thereby considerably minimizing the dishing. Accordingly, if the contact hole etch for forming the bit line contact on the cell landing plug contacts 100 is employed, the CD of the contact hole is not decreased.

Next, as shown in FIG. 3D, a subsequent thermal process is performed at a relatively low temperature, thereby re-growing the cell landing plug contacts 100 into an epitaxial silicon layer 100A. At this time, the amorphous silicon layer 31 comprising the cell landing plug contacts 100 is re-grown into the epitaxial silicon layer 30, thereby making all of the cell landing plug contacts 100 into the epitaxial silicon layer 100A. The subsequent thermal process for re-growing the epitaxial silicon layer 100A is performed at a temperature ranging form approximately 500° C. to approximately 700° C. for a predetermined time. For instance, the subsequent thermal process can be performed at approximately 500° C. for approximately 10 hours, or can be performed at approximately 700° C. for approximately 30 minutes.

As a result, the cell landing plug contacts 100 being comprised of the epitaxial silicon layer 100A are formed through the subsequent thermal process.

In accordance with the first embodiment of the present invention, a thermal process for re-growing the contact material formed through a SPE process into an epitaxial silicon layer is employed after a CMP process, thereby obtaining a cell landing plug contact having a good property in dishing.

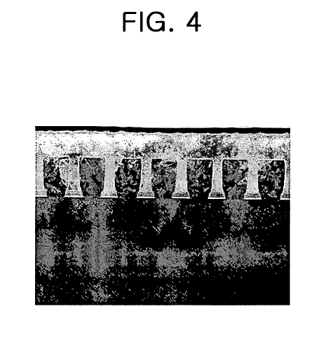

FIG. 4 is a diagram illustrating a result obtained after a CMP process in accordance with the first embodiment of the present invention. It should be noted that the dishing is minimized since the CMP process is only employed with respect to an amorphous silicon layer.

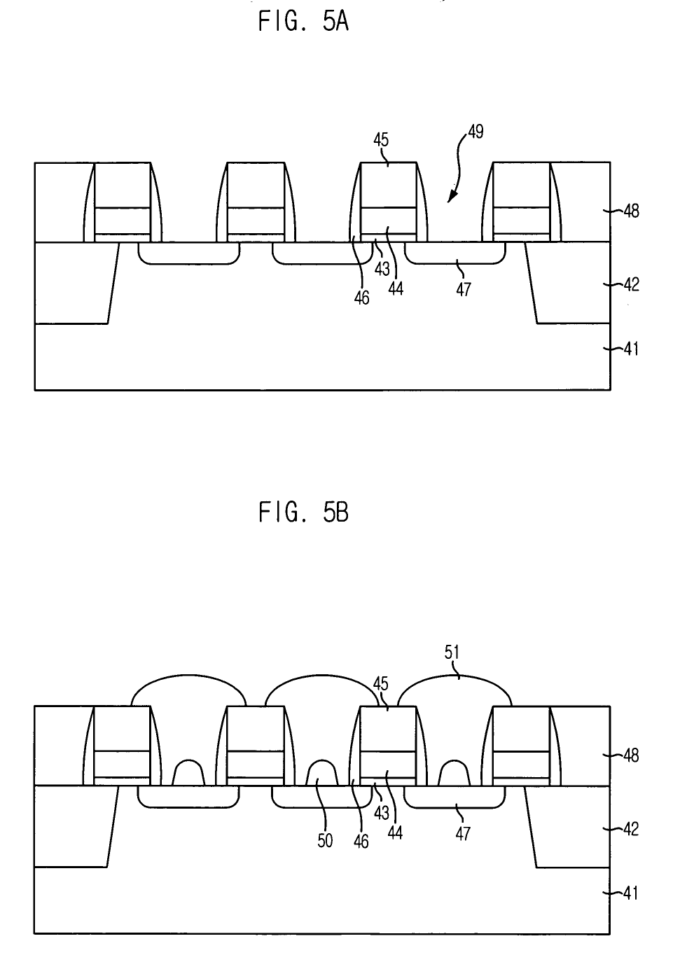

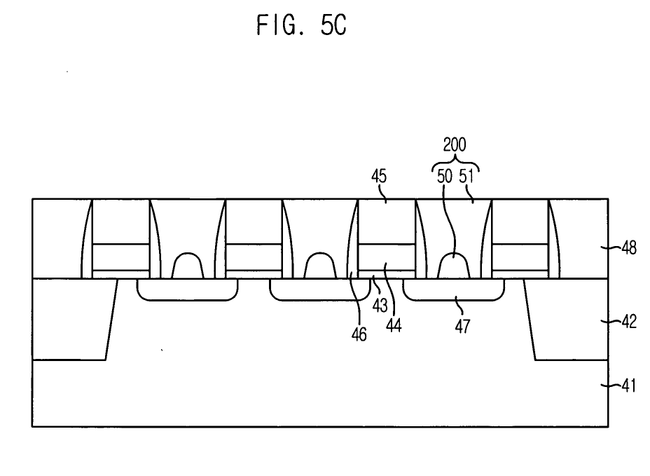

FIGS. 5A to 5C are cross-sectional views illustrating a method for fabricating a contact of a semiconductor device in accordance with a second embodiment of the present invention.

As shown in FIG. 5A, a device isolation process for isolating devices from each other is performed on a substrate 41, thereby forming a device isolation layer 42. Afterwards, a plurality of gate patterns formed by sequentially stacking a gate insulation layer 43, a gate electrode 44, a gate hard mask 45 are formed on selected regions of the substrate 41.

Subsequently, an insulation layer is deposited on the substrate 41 including the plurality of gate patterns and then, a blanket etch is performed, thereby forming a plurality of gate spacers 46 contacted on the sidewalls of the gate patterns. At this time, the gate hard mask 45 and the gate spacers 46 use a material having an etch selectivity with respect to a subsequent inter-layer insulation layer. If the inter-layer insulation layer is a silicon oxide layer, a silicon nitride layer is used for forming the gate hard mask 45 and the gate spacers 46.

Next, a plurality of junctions 47 serving the role of a source/drain of a transistor are formed on the substrate 41 exposed between the plurality of gate patterns by employing a typical ion-implantation process. Herein, the junctions 47 can be a lightly doped drain (LDD) structure, and N-type dopants such as arsenic (As) or P-type dopants such as boron (B) are implanted to the junctions 47.

Next, an inter-layer insulation layer 48 is deposited on the substrate 41 including the plurality of gate patterns. At this time, the inter-layer insulation layer 48 uses an oxide compound. Particularly, a silicon oxide-based material selected from a group consisting of BPSG, USG, TEOS, PSG and BSG is used.

Next, a chemical mechanical polishing (CMP) process is performed until upper portions of the gate patterns are exposed, thereby planarizing the inter-layer insulation layer 48. Subsequently, a contact mask is formed through a photolithography process, e.g., a deposition of a photoresist layer, and photo-exposure and developing processes. Afterwards, the inter-layer insulation layer 48 is etched by using the contact mask (not shown) as an etch mask, thereby forming a plurality of contact holes 49 for forming a cell landing plug contact.

At this time, since there is lack of a photolithography process margin with respect to a lower layer as for a highly integrated device, the inter-layer insulation layer 48 is subject to a self-aligned contact (SAC) etching process under a condition that an etch selectivity of the inter-layer insulation layer 48 is good with respect to those of the gate hard mask 45 and the spacers 46. Accordingly, the silicon oxide-based material used for forming the inter-layer insulation layer 48 exposed through the photolithography process is etched in a fast speed. However, since the etch speed of the silicon nitride layer used for forming the gate hard mask 45 and the gate spacers 46 is slow, a silicon nitride-based layer deposited on upper portions or sidewalls of the gate patterns is more or less protected and the junctions 47 of the substrate 41 are exposed.

Meanwhile, etch residues (not shown) exist on sidewalls and low portions of the plurality of contact holes 49 formed by etching the inter-layer insulation layer 48 and a latticed silicon defect is generated on a surface of the junctions 47 due to an etching process. Furthermore, a native oxide layer is formed on surfaces of the junctions 47 exposed by forming the contact holes 49. The etch residues degrade the leakage current property of a device and the native oxide layer increases the contact resistance, thereby providing a factor degrading the electrical property of the device.

Accordingly, after the plurality of contact holes 49 are formed, a pre-cleaning process, e.g., a dry cleaning process or a wet cleaning process, performed before forming the contact material is employed. The wet cleaning process uses a hydrogen fluoride (HF)-last cleaning that applies a solution of HF at the last, or a buffered oxide echant (BOE)-last cleaning that uses a solution of BOE at the last. The dry cleaning process applies a plasma cleaning. The pre-cleaning process is employed at a temperature ranging from approximately 25° C. to approximately 500° C.

The HF-last cleaning proceeds a HF-based cleaning at the last. The HF-last cleaning uses a chemical solution selected from a group consisting of RNO[R(H₂SO₄+H₂O₂)+N(NH₄OH+H₂O₂)+O(HF-based BOE)], RNF [R (H₂SO₄+H₂O₂)+N (NH₄OH+H₂O₂)+HF], RO, NO and RF. Herein, R is referred as SPM that is a mixture of sulfuric (H₂SO₄) and peroxide (H₂O₂).

A gas used during performing the plasma cleaning process is selected from a group consisting of an hydrogen (H₂) gas, a mixed gas of H₂ and nitrogen (N₂), a chlorine fluoride (CF) based gas, a nitrogen fluoride (NF) based gas and a nitrogen hydride (NH) based gas. For instance, H₂, H₂/N₂, nitrogen trifluoride (NF₃), ammonia (NH₃) and tetrafluoromethane (CF₄) are used.

The pre-cleaning process described above is performed continuously without a time delay to maintain a clean condition of exposed portions of the contact holes 49 and a solid phase epitaxy (SPE) process is also performed without a time delay after employing the pre-cleaning process.

As shown in FIG. 5B, the SPE process is employed, thereby growing an amorphous silicon layer 51 filling the plurality of contact holes 49 in a thickness ranging from approximately 300 Å to approximately 3,000 Å. At this time, during the SPE process, an epitaxial silicon layer 50 is formed on the bottom surfaces of the plurality of contact holes 49 at an early deposition state. As the deposition proceeds, the amorphous silicon layer 51 is formed on the epitaxial silicon layer 50.

For instance, the SPE process for growing the epitaxial silicon layer 50 and the amorphous silicon layer 51 is employed in an H₂ atmosphere along with supplying a mixed gas of SiH₄ and PH₃ at a pressure ranging from approximately 150 torr to approximately 200 torr and a temperature ranging from approximately 400° C. to approximately 700° C. for a predetermined time. For instance, the SPE process can be performed at approximately 400° C. for approximately 20 minutes, or can be performed at approximately 700° C. for approximately 3 minutes. Herein, the SPE process is performed for a longer period at a lower temperature. At this time, a flowing amount of SiH₄ ranges from approximately 500 sccm to approximately 800 sccm and a flowing amount of PH₃ ranges from approximately 20 sccm to approximately 50 sccm. As described above, the PH₃ gas that is the doping gas is flowed while the amorphous silicon layer 51 is being grown, thereby maintaining a doping concentration of P within the amorphous silicon layer 51 at a relatively low level ranging from approximately 1×10¹⁹ atoms/cm³ to approximately 1×10²¹ atoms/cm³.

Meanwhile, it is possible for As to be used as an impurity doped within the amorphous silicon layer 51. At this time, during growing the amorphous silicon layer 51, AsH₃ is flowed as a doping gas. It is preferable to perform the SPE process doping As in an H₂ gas atmosphere at a pressure ranging from approximately 150 torr to approximately 200 torr and a temperature ranging from approximately 400° C. to approximately 700° C. for a predetermined time along with supplying a mixed gas of SiH₄ and AsH₃. For instance, the SPE process can be performed at approximately 400° C. for approximately 30 minutes, or can be performed at approximately 700° C. for approximately 3 minutes. Herein, the SPE process is performed for a longer period at a lower temperature. At this time, a flowing amount of SiH₄ ranges from approximately 500 sccm to approximately 800 sccm and a flowing amount of AsH₃ ranges from approximately 20 sccm to approximately 50 sccm. As shown above, the AsH₃ gas that is the doping gas is flowed while the amorphous silicon layer 51 is being grown, thereby maintaining a doping concentration of As at a relatively low level ranging from approximately 1×10¹⁹ atoms/cm³ to approximately 1×10²¹ atoms/cm³.

A deposition method for growing the amorphous silicon layer 51 through the SPE process as described above includes one selected from a group consisting of a RPCVD method, a LPCVD method, a VLPCVD method, a PECVD method, an UHVCD method, an APCVD method and a MBE.

Although the amorphous silicon layer 51 and the epitaxial silicon layer 50 used as the contact materials are formed through the SPE process, Ge and SiGe in addition to silicon can also be used as the contact material formed through the SPE process. That is, it is possible to use an epitaxial Ge layer/an amorphous Ge layer and an epitaxial SiGe layer/an amorphous SiGe layer as the contact materials.

Meanwhile, the first reason why the epitaxial silicon layer 50 can grow under the early deposition state during the SPE process is because the epitaxial silicon layer 50 is loaded into an amorphous layer deposition apparatus, e.g., an amorphous silicon deposition apparatus, in a vacuum without any time delays after the pre-cleaning process is performed. During performing the pre-cleaning process, if the SPM formed by mixing approximately 1 part of H₂SO₄ and approximately 20 parts of H₂O₂ at a temperature of approximately 90° C. and a solution of BOE formed by mixing approximately 300 parts of NH₄ and 1 part of HF are used, the surface of the substrate is subjected to a hydrogen treatment, i.e., a state that a silicon dangling bond of the silicon substrate is combined with hydrogen, thereby preventing the growth of the native oxide layer for a predetermined period. As described above, since the growth of the native oxide layer is prevented, the epitaxial silicon layer 50 is grown at the early deposition state during the SPE process. The second reason why the epitaxial silicon layer 50 can grow under the early deposition state of the SPE process is because an atmosphere gas introduced to deposit the amorphous silicon layer 51 is the H₂ gas. That is, as the H₂ gas is used, the gas atmosphere becomes a deoxidizing atmosphere instead of an oxidizing atmosphere. Thus, the epitaxial silicon layer 50 can grow even in the early deposition state of the amorphous silicon layer 51 due to the deoxidizing atmosphere.

As shown in FIG. 5C, the amorphous silicon layer 51 is subjected to a CMP process and becomes planarized, thereby forming a plurality of cell landing contact plugs 200 isolated from each other. That is, the plurality of cell landing contact plugs 200 are comprised of the epitaxial silicon layer 50 and the amorphous silicon layer 51. During the CMP process, only the amorphous silicon layer 51 is planarized.

As described above, in accordance with the present invention, a subsequent thermal process for re-growing the amorphous silicon 51 that is the contact material formed through the SPE process into the epitaxial silicon layer 51 is not performed. Instead, the CMP process is directly performed, thereby forming the plurality of cell landing plug contacts 200. The plurality of cell landing plug contacts 200 become a dual layer formed with the epitaxial silicon layer 50 and the amorphous silicon layer 51.

Accordingly, a region removed through the CMP process is the amorphous silicon layer 51 among the contact materials formed through the SPE process. Dishing caused by the CMP process employed to the amorphous silicon layer 51 is smaller than that caused by the CMP process employed to the epitaxial layer 50 by a thickness ranging from approximately 50 Å to approximately 100 Å, thereby considerably minimizing the dishing. Accordingly, if the contact hole etch for forming the bit line contact on the cell landing plug contacts 200 is employed, the CD of the contact hole is not decreased.

Unlike the first embodiment of the present invention, in accordance with the second embodiment of the present invention described above, a subsequent low temperature thermal process for re-growing an amorphous silicon layer into an epitaxial silicon layer is not employed to cell landing plug contacts. However, even though the low temperature thermal process is not separately employed, a thermal process, e.g. a rapid thermal process or a furnace thermal process, accompanied by a process for fabricating a subsequent semiconductor device is performed several times at a temperature ranging from approximately 500° C. to approximately 700° C. Accordingly, it is possible to sufficiently re-grow the amorphous silicon layer into the epitaxial silicon layer. Thus, the second embodiment that does not separately perform the thermal process for re-growing the amorphous silicon layer into the epitaxial silicon layer is more advantageous in view of a simplification of a process and a decrease in a thermal budget during performing a process for fabricating a semiconductor device compared with the first embodiment of the present invention.

In accordance with the first and the second embodiments of the present invention, a contact material is formed through a SPE process and then, a subsequent thermal process for re-growing an amorphous silicon layer into an epitaxial silicon layer is performed after a CMP process or omitted.

Also, a CMP process is only performed with respect to an amorphous silicon layer due to a SPE process and thus, there is not a decreasing problem in a BLC CD because the CMP process performed to the amorphous silicon layer provides an identical situation to that the CMP process performed to polysilicon provides.

In accordance with the present invention, a subsequent thermal process for a re-growth during performing a SPE process is omitted or performed after a CMP process for forming a plurality of cell landing plug contacts, thereby providing the effect of decreasing the contact resistance of a semiconductor device and improving reliability and yields of products.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a contact plug of a semiconductor device, the method comprising:
providing a plurality of junctions on a substrate;
forming an inter-layer insulation layer over the substrate and the junctions;
forming a plurality of contact holes to expose the junctions by etching the inter-layer insulation layer;
forming contact layers that fill the contact holes, the contact layers including an epitaxy layer and an amorphous layer, the contact layers formed by using a solid phase epitaxy (SPE) process; and
forming a plurality of cell landing plug contacts by selectively planarizing the amorphous layer of the contact layers.

2. The method of claim 1, wherein the epitaxial layer is provided in first regions that contact the junctions and the amorphous layer is formed on the epitaxial layer.

3. The method of claim 2, wherein the amorphous layer is formed on second regions that contact the junctions, the first and second regions being different.

4. The method of claim 1, further including:
performing a pre-cleaning process to remove a native oxide layer on a bottom surface of the contact holes; and
performing a subsequent thermal process for re-growing the contact layers forming the plurality of cell landing plug contacts into the epitaxial layer after forming the plurality of cell landing plug contacts.

5. The method of claim 4, wherein the subsequent thermal process is performed in an nitrogen atmosphere at a temperature ranging from approximately 500° C. to approximately 700° C. for a period ranging from approximately 3 minutes to approximately 10 hours according to the temperature of the thermal process, wherein the duration of the thermal process is inversely proportional to the process temperature.

6. The method of claim 1, wherein the step for forming the contact layers is performed by loading the substrate into an amorphous layer deposition apparatus in a vacuum after employing the pre-cleaning process.

7. The method of claim 6, wherein the step of forming the contact layers is performed through one selected from a group consisting of a reduced pressure chemical vapor deposition (RPCVD) method, a low pressure chemical vapor deposition (LPCVD) method, a very low pressure chemical vapor deposition (VLPCVD) method, a plasma enhanced chemical vapor deposition (PECVD) method, an ultra high vacuum chemical vapor deposition (UHVCD) method, an atmosphere pressure chemical vapor deposition (APCVD) and a molecular beam epitaxy (MBE).

8. The method of claim 1, wherein the SPE process for forming the contact layers comprised of the epitaxial layer and the amorphous layer is performed at a pressure ranging from approximately 150 torr to approximately 200 torr and a temperature ranging from approximately 400° C. to approximately 700° C. for a period ranging from approximately 3 minutes to approximately 20 minutes, wherein the duration of the thermal process is inversely proportional to the process temperature.,
wherein the SPE process further involves supplying a mixed gas of silane (SiH₄) and a doping gas, wherein a flow rate of SiH₄ ranges from approximately 500 sccm to approximately 800 sccm and a flow rate of the doping gas ranges from approximately 20 sccm to approximately 50 sccm.

9. The method of claim 8, wherein a doping concentration of phosphorous (P) within the amorphous layer is maintained at a level ranging from approximately 1×10¹⁹ atoms/cm³ to approximately 1×10²¹ atoms/cm³, the doping gas including phosphine (PH₃).

10. The method of claim 8, wherein a doping concentration of arsenic (As) within the amorphous layer is maintained at a level ranging form approximately 1×10¹⁹ atoms/cm³ to approximately 1×10²¹ atoms/cm³, the doping gas including arsine (AsH₃).

11. The method of claim 8, wherein the step for forming the contact layers is performed in a hydrogen (H₂) gas atmosphere.

12. The method of claim 1, wherein the contact layers are formed in a layer selected from a group consisting of a silicon (Si) layer, a germanium (Ge) layer and a silicon germanium (SiGe) layer.

13. The method of claim 1, wherein the contact layers are formed in a thickness ranging from approximately 300 Å to approximately 3,000 Å at a temperature ranging from approximately 400° C. to approximately 700° C.

14. The method of claim 1, wherein the pre-cleaning process is performed through one of a dry cleaning process and a wet cleaning process.

15. The method of claim 14, wherein the wet cleaning process includes one of a hydrogen fluoride (HF)-last cleaning process and a buffered oxide etchant (BOE)-last cleaning process.

16. The method of claim 15, wherein the dry cleaning process includes a plasma cleaning process and a thermal bake process.

17. The method of claim 16, wherein a gas used during performing the plasma cleaning process is selected from a group consisting of H₂, H₂/N₂, nitrogen trifluoride (NF₃), ammonia (NH₃) and tetrafluoromethane (CF₄).
